(19) United States
(12) Patent Application Publication
(10) Pub. No.: US 2007/0072412 A1
(43) Pub. Date: Mar. 29, 2007

(54) PREVENTING DAMAGE TO INTERLEVEL DIELECTRIC

(75) Inventors: Derren N. Dunn, Sandy Hook, CT (US); Nicholas C.M. Fuller, Ossining, NY (US); Catherine Labelle, Wappingers Falls, NY (US); Vincent J. McGahay, Poughkeepsie, NY (US); Sanjay C. Mehta, Poughkeepsie, NY (US); Henry A. Nye III, Brookfield, CT (US)

Correspondence Address: HOFFMAN, WARNICK & D'ALESSANDRO LLC, 75 STATE ST, 14TH FL, ALBANY, NY, 12207, US

(73) Assignees: INTERNATIONAL BUSINESS MACHINES CORPORATION, Armonk (US); ADVANCED MICRO DEVICES, INC. (AMD), Sunnyvale, CA (US)

(21) Appl. No.: 11/162,883

(22) Filed: Sep. 27, 2005

(51) Int. Cl. H01L 21/4763; H01L 21/311

(52) U.S. Cl. 438/639; 438/700; 438/702; 438/703; 438/696; 438/694; 257/E21.278; 257/E21.579

(57) ABSTRACT

Prevention of damage to an interlevel dielectric (ILD) is provided by forming an opening (e.g., trench) in the ILD, and sputtering a dielectric film onto a sidewall of the opening by overetching into a layer of the dielectric below or within the ILD during forming of the opening. The re-sputtered film protects the sidewall of the opening from subsequent plasma/ash processes and seals the porous dielectric surface along the sidewall and bottom without impacting overall process throughput. A semiconductor structure resulting from the above process is also disclosed.

### BACKGROUND OF THE INVENTION

1. Technical Field

The invention relates generally to the semiconductor fabrication, and more particularly, to preventing damage to an opening of a low dielectric constant (low-k) interlevel dielectric (ILD) by sputtering a dielectric film onto the sidewall of the opening in the ILD. The invention also relates to preventing damage to the opening sidewall by pore sealing along the opening sidewall in the case where a porous film is employed as the ILD.

2. Background Art

In the semiconductor fabrication industry, the pursuit of ever smaller devices has lead to the use of ultra low dielectric constant (“ultra low-k”) materials such as porous carbon-doped silicon dioxide (pSiCOH). Many of these ultra low-k materials have a dielectric constant between 1.8 and 2.7. The transition of conventional back-end-of-the line (BEOL) integration schemes to ultra-low-k dielectrics, however, poses significant challenges. In particular, one of the most significant issues is the susceptibility of the porous interlevel dielectrics (ILD) to plasma etch/ash induced damage. The conventional ashing chemistries cause long range damage in sidewalls of openings, e.g., trenches, in the porous ILDs. The damage manifests itself, for example, as a depletion of carbon from the porous ILD, which results in silanol formation due to moisture uptake. The silanol formation and carbon depletion both lead to increase in the interline capacitance and effective dielectric constant (k_{eff}) of a stack.

One approach to minimize ash-induced damage is by employing downstream oxidizing ash processes such as, but not limited to, those including: oxygen/carbon monoxide (O₂/CO), argon/oxygen (Ar/O₂) or ammonia/oxygen (NH₃/O₂). In addition to the downstream oxidizing process, or as an alternative thereto, downstream reducing ash processes conducted at elevated substrate temperature (such as helium/hydrogen (He/H₂)) may also be employed. However, each of these processes is incompatible with the organic films in the stack. Thus, the dielectric stack has to be carefully selected so that the stack integrity is not jeopardized by the downstream ash processes.

Some porous ILDs with dielectric constants in the range of 1.8 to 2.5 also have an interconnected pore structure. The interconnected porosity poses a real challenge for the application of advanced liner processes (e.g., thermal and ion-induced atomic layer deposition (iALD), or plasma-enhanced chemical vapor deposition (PECVD)) due to chemical precursors penetrating into the ILD, resulting in degraded back-end-of-line (BEOL) performance, including increased leakage and reduced reliability.

A number of approaches have been employed to address this situation. In one approach, a pore-sealing layer is provided by spin-on chemistries. This approach, however, is not ideal because the non-uniformity of coverage within and across different features (e.g., sidewall versus an opening bottom, different size openings, pattern density dependence, etc.), and the additional burden on the liner process to clean up the bottom of vias to ensure good electrical contact. In another approach, PECVD deposition of a dense low-k SiCOH film has been proposed. Unfortunately, while this approach solves the non-uniformity issue, it adds an extra step in the process flow, impacting the throughput and overall cost.

In view of the foregoing, there is a need in the art for a solution that prevents ash-induced damage to, and prevents CVD/ALD precursor penetration into, porous ILDs with minimal or no impact on the process flow and throughput.

### SUMMARY OF THE INVENTION

Prevention of damage to an interlevel dielectric (ILD) is provided by forming an opening (e.g., trench) in the ILD, and sputtering a dielectric film onto a sidewall of the opening by overetching into a layer of the dielectric below or within the ILD during forming of the opening. The re-sputtered film protects the sidewall of the opening from subsequent plasma/ash processes and seals the porous dielectric surface along the sidewall and bottom without impacting overall process throughput. A semiconductor structure resulting from the above process is also disclosed.

A first aspect of the invention includes a method of preventing damage to an interlevel dielectric (ILD), the method comprising the steps of: forming an opening in the ILD; and preventing damage to the ILD by sputtering a dielectric film onto a sidewall of the opening by overetching into a portion of dielectric film during forming of the opening.

A second aspect of the invention provides a method of preventing damage to a porous interlevel dielectric (ILD) during an ash process, the method comprising the steps of: forming an opening in the porous ILD; sputtering a dielectric film onto a sidewall of the opening by overetching into a portion of dielectric during forming of the opening, wherein the dielectric film seals pores of the ILD; and performing the ash process using the dielectric film to prevent damage to the porous ILD.

A third aspect of the invention includes a semiconductor structure comprising: a dielectric stack including an opening in a porous interlevel dielectric (ILD) and a portion of dielectric; a protective sidewall film in the opening adjacent the porous ILD, the protective sidewall film sealing pores of the porous ILD; a liner in the opening adjacent to the protective sidewall film; and a metal in the opening adjacent to the liner.

The illustrative aspects of the present invention are designed to solve the problems herein described and other problems not discussed, which are discoverable by a skilled artisan.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIGS. 1-5 show steps of one embodiment of a method according to the invention.

FIGS. 6A-B show semiconductor structures resulting from the method of FIGS. 1-5.

It is noted that the drawings of the invention are not to scale. The drawings are intended to depict only typical aspects of the invention, and therefore should not be considered as limiting the scope of the invention. In these drawings, like numbering represents like elements.

### DETAILED DESCRIPTION

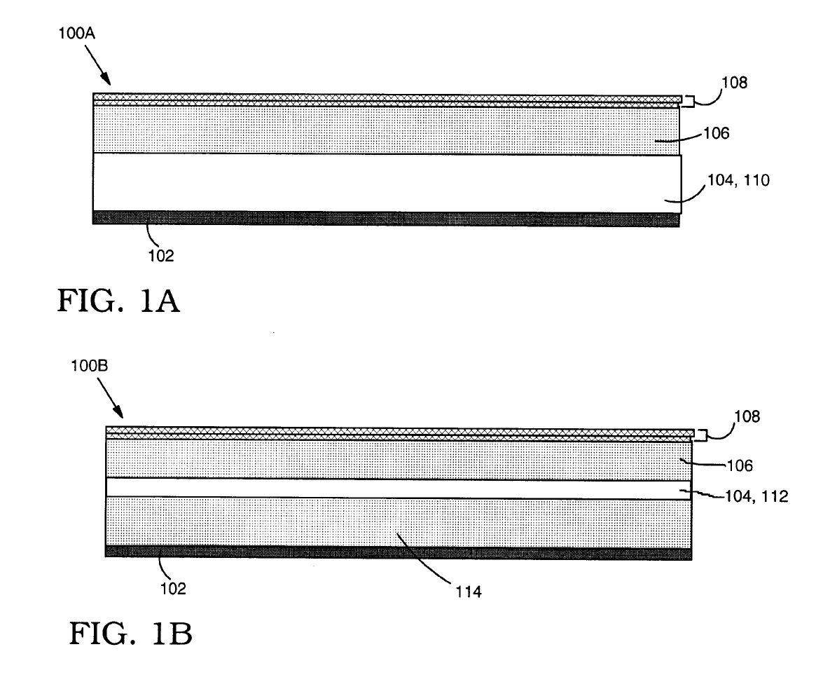

Turning to the drawings, FIGS. 1A and 1B show a preliminary structure 100A and 100B, respectively, to which a method according to one embodiment of the invention will be applied. Structures 100A and 100B include, inter alia, a base layer 102 such as a cap layer of an underlying level (not shown), a dielectric portion 104, an (opening level) interlevel dielectric (ILD) 106 over dielectric portion 104, and a multiple layer hard mask 108. In one embodiment, shown in FIG. 1A, dielectric portion 104 may include a (via level) dielectric layer 110 under ILD 106. Alternatively, in another embodiment, shown in FIG. 1B, dielectric portion 104 may be implemented as an etch stop layer 112 between ILD 106 and another interlevel dielectric 114. For purposes of clarity, dielectric portion 104 will be described hereafter as a layer under ILD 106. It should be recognized, however, that implementation as etch stop layer 112 between ILD 106 and another interlevel dielectric 114, as will be described below, will result in the same advantages.

In one embodiment, ILDs 106 and 114 may be porous ultra low dielectric constant material, i.e., k of about 1.8-2.4. In one embodiment, ILDs 106 and 114 may include PECVD porous SiCOH or spun-on materials such as hydrogensilsesquioxanes (HSQ), methylsilsesquioxanes (MSQ) or polyarylene ethers (PAE). A porous dielectric, however, is preferred for ILD 106, i.e., the upper layer. Dielectric portion 104 in the form of via level layer 110 (FIG. 1A) under ILD 106 may include any of the preceding dielectrics, or a dense dielectric material, e.g., SiCOH with k=about 2.5-3.0, or silicon dioxide (SiO₂). When dielectric portion 104 is provided as etch stop layer 112 (FIG. 1B), it may include: PECVD silicon dioxide (SiO₂), silicon nitride (Si₃N₄), silicon carbon nitride (SiCN), silicon oxycarbide (SiOC), silicon oxy-nitride (SiON). In one preferred embodiment, dielectric portion 104 is silicon dioxide (SiO₂). Dielectric portion 104 may also include a combination of the materials listed above.

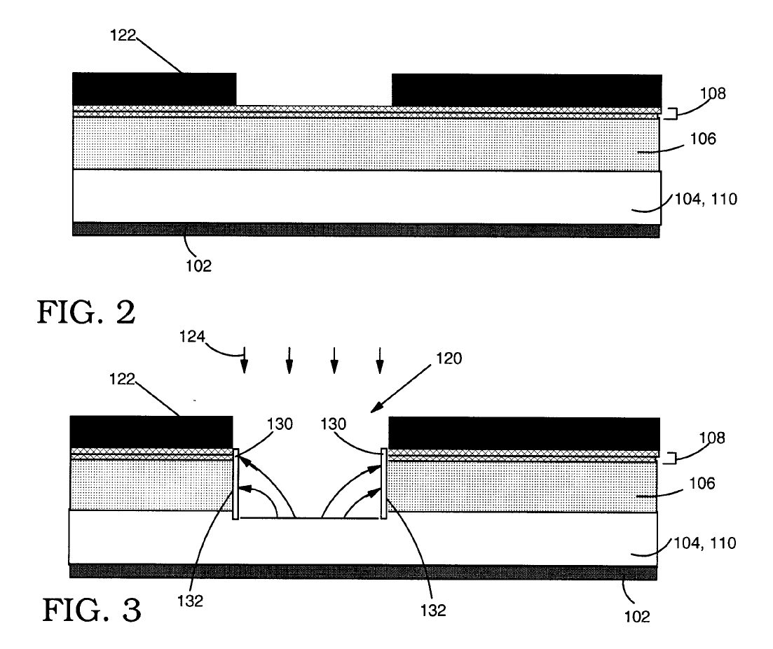

Next, as shown in FIGS. 2-3, an opening 120 (FIG. 3) is formed in ILD 106. Opening 120 may be formed by any now known or later developed manner such as by deposition, patterning and etching of a mask 122, and then etching 124 (e.g., reactive ion etching (RIE)) through ILD 106.

FIG. 3 also shows a step of preventing damage to ILD 106 according to one embodiment of the invention. In particular, during formation of opening 120, i.e., etching 124, a dielectric film 130 is sputtered onto a sidewall 132 of opening 120 by overetching into dielectric portion 104. That is, the sputtered dielectric from the bottom of opening 120 in ILD 106 is re-deposited on sidewalls 132 of opening 120 in ILD 106. The same structure would be formed if the stack had the configuration of FIG. 1B. Dielectric film 130 thus may include the same material as dielectric portion 104, such as silicon dioxide (SiO₂). Where ILD 106 includes a porous material, dielectric film 130 also preferably seals pores of ILD 106, which prevents a deposition precursor for a liner from penetrating the pores of ILD 106, enabling the deposition of ALD and CVD liners. Thus, this methodology would alleviate the risk of high interline leakage and BEOL reliability. A thickness of dielectric film 130 may be controlled by controlling a depth of the overetching into dielectric portion 104. In one embodiment, dielectric film 130 has a thickness of no less than about 500 Å and no greater than about 3000 Å, and preferably no less than about 1500 Å and no greater than about 2000 Å. In addition, in one embodiment, the overetching has a depth of no less than about 100° A. and no greater than about 600 Å, and preferably about 300 Å.

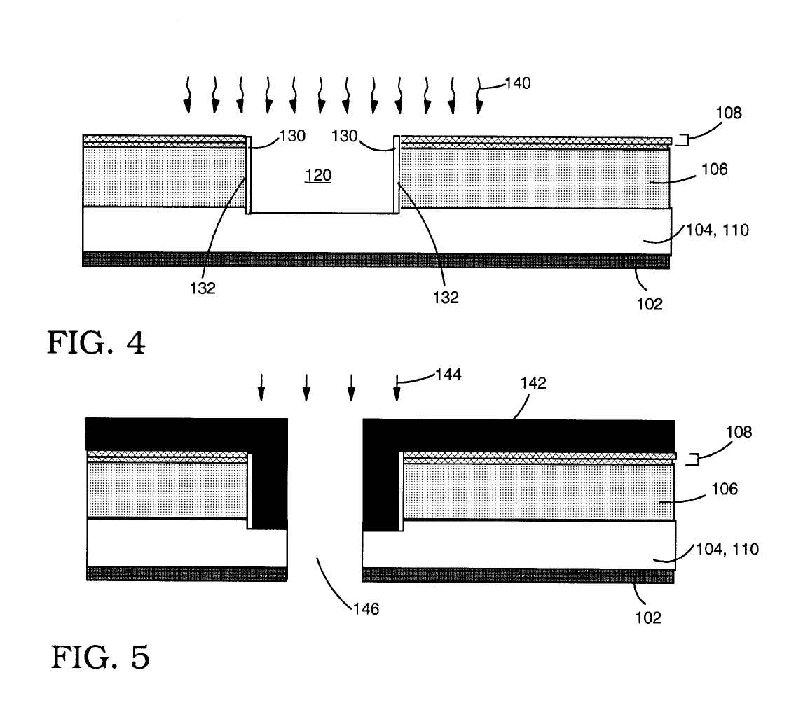

FIG. 4 shows a next step of performing a plasma etch (ashing process) 140 to remove mask 122 (FIGS. 2-3) after the sputtering step. Dielectric film 130 protects ILD 106 during this step, thus preventing damage to ILD 106.

FIG. 5 shows optional subsequent steps including, for example, forming a mask 142 and etching 144 a via opening 146 through the rest of dielectric portion 104 in the case of dielectric portion 104 is a via level layer 110, and base layer 102.

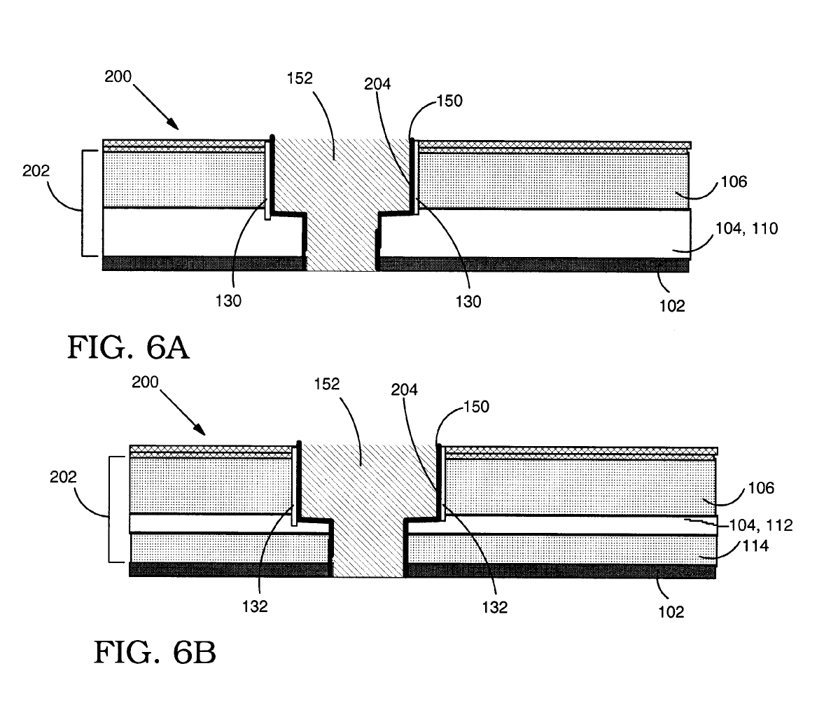

FIGS. 6A-B show the completion of subsequent conventional steps including, for example, depositing a liner 150 and then filling with metal 152, e.g., copper (Cu), both opening 120 (FIG. 4) and via opening 146 (FIG. 5). During deposition of liner 150, a deposition precursor is deposited (not shown). Dielectric film 130 prevents penetration of deposition precursor and liner 150 into the pores of ILD 106.

FIG. 6A also shows a semiconductor structure 200 formed using the above-described methods. Structure 200 includes a dielectric stack 202 including an opening 204 in a porous interlevel dielectric (ILD) 106 and a silicon dioxide (SiO₂) layer 110 below porous ILD 106. In addition, a protective sidewall (dielectric) film 130 is provided in opening 204 adjacent porous ILD 106. Protective sidewall film 130 seals pores of porous ILD 106. A liner 150 is also provided in opening 204 adjacent to protective sidewall film 130, and a metal 152 is provided in opening 204 adjacent to liner 150. FIG. 6B shows the same semiconductor structure 200 formed using the above-described methods based on the initial structure of FIG. 1B.

The above-described method prevents damage to an ILD and is ideally suited for an opening (trench) first hybrid integration scheme where the via level dielectric portion 110 is silicon dioxide (SiO₂) and the opening level ILD 106 is either dense or porous CVD/spin-on film. However, as mentioned earlier, it can also be applied to a full porous dielectric stack with a silicon dioxide (SiO₂) etch stop layer 112 in the center of the stack, as shown in FIG. 1B. The above-described method may also allow use more aggressive ash chemistries such as N₂H₂ and O₂-CO chemistries.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

1. A method of preventing damage to an interlevel dielectric (ILD), the method comprising the steps of:
forming an, opening through the ILD; and
preventing damage to the ILD by sputtering a dielectric film onto a sidewall of the opening by overetching into a portion of a dielectric film layer below the ILD during forming of the opening.

2. The method of claim 1, further comprising the step of performing a plasma etch to remove a mask after the sputtering step, whereby the dielectric film protects the ILD.

3. The method of claim 1, wherein the ILD includes a porous material and the sputtering step includes the dielectric film sealing pores of the ILD.

4. The method of claim 3, further comprising the step of depositing a liner in the opening, wherein the dielectric film prevents penetration of a deposition precursor for the liner into the pores of the ILD.

5. The method of claim 1, further comprising the step of controlling a thickness of the dielectric film by controlling a depth of the overetching into the portion of the dielectric film.

6. The method of claim 1, wherein the dielectric film includes at least one of the following: pSiCOH, hydrogen silsesquioxanes (HSQ), methyl silsesquioxanes (MSQ) or polyarylene ether (PAE), dense SiCOH, silicon dioxide (SiO₂), silicon nitride (Si₃N₄), silicon carbon nitride (SiCN), silicon oxycarbide (SiOC) and silicon oxy-nitride (SiON).

7. The method of claim 1, wherein the ILD includes a material selected from the group consisting of: plasma-enchanced chemical vapor deposition (PECVD) pSiCOH, spin-on hydrogen silsesquioxanes (HSQ), spin-on methyl silsesquioxanes (MSQ) and spin-on polyarylene ethers (PAE).

8. The method of claim 1, wherein the dielectric film has a thickness of no less than about 500 Å and no greater than about 3000 Å.

9. The method of claim. 8, wherein the dielectric film has a thickness of no less than about 1500 Å and no greater than about 2000 Å.

10. The method of claim 1, wherein the overetching has a depth of no less than about 100 Å and no greater than about 600 Å.

11. The method of claim 1, wherein the overetching has a depth of about 300 Å.

12. The method of claim 1, wherein the portion of the dielectric film includes one of: a layer of the dielectric under the ILD, and an etch stop layer of the dielectric film between the ILD and another interlevel dielectric.

13. A method of preventing damage to a porous interlevel dielectric (ILD) during an ash process, the method comprising the steps of:
forming an opening through the porous ILD;
sputtering a dielectric film onto a sidewall of the opening by overetching into a portion of a dielectric below the ILD during forming of the opening, wherein the dielectric film seals pores of the ILD; and
performing the ash process using the dielectric film to prevent damage to the porous ILD.

14. The method of claim 13, further comprising the step of depositing a liner in the opening, wherein the dielectric film prevents penetration of a deposition precursor for the liner into the pores of the ILD.

15. The method of claim 13, further comprising the step of controlling a thickness of the dielectric film by controlling a depth of the overetching into the portion of dielectric.

16. The method of claim 13, wherein the ILD includes a material selected from the group consisting of: plasma-enchanced chemical vapor deposition (PECVD) pSiCOH, spin-on hydrogen silsesquioxanes (HSQ), spin-on methylsilsesquioxanes (MSQ) and polyarylene ethers (PAE).

17. The method of claim 13, wherein the dielectric film has a thickness of no less than about 500 Å and no greater than about 3000 Å, and the overetching has a depth of no less than about 100 Å and no greater than about 600 Å.

18. The method of claim 13, wherein the portion of the dielectric includes one of: a layer of the dielectric under the ILD, and an etch stop layer of the dielectric between the ILD and another interlevel dielectric.

19. A semiconductor structure comprising:
a dielectric stack including an opening in a porous interlevel dielectric (ILD) and a portion of dielectric;
a protective sidewall film in the opening adjacent the porous ILD, the protective sidewall film sealing pores of the porous ILD;
a liner in the opening adjacent to the protective sidewall film; and
a metal in the opening adjacent to the liner.

20. The semiconductor structure of claim 19, wherein the dielectric portion includes one of: a layer of the dielectric under the ILD, and an etch stop layer of the dielectric between the ILD and another interlevel dielectric.
